(19) United States
(12) Patent Application Publication
(10) Pub. No.: US 2025/0159902 A1
(43) Pub. Date: May 15, 2025

(54) SEMICONDUCTOR STRUCTURE AND PREPARATION METHOD THEREOF

(71) Applicant: XIAMEN INDUSTRIAL TECHNOLOGY RESEARCH INSTITUTE CO., LTD., Xiamen (CN)

(72) Inventors: Enping CHENG, Xiamen (CN); Taiwei CHIU, Xiamen (CN); Tingying SHEN, Xiamen (CN); Wuxin LI, Xiamen (CN); SZU-CHUN KANG, Xiamen (CN); Anqiao CHEN, Xiamen (CN); Xiaoli SU, Xiamen (CN)

(73) Assignee: XIAMEN INDUSTRIAL TECHNOLOGY RESEARCH INSTITUTE CO., LTD., Xiamen (CN)

(21) Appl. No.: 18/928,224

(22) Filed: Oct. 28, 2024

(30) Foreign Application Priority Data
Nov. 9, 2023 (CN) 202311485763 .5

(51) Int. Cl. H10B 63/00; H10N 70/00

(52) U.S. Cl. CPC H10B 63/20; H10N 70/841

(57) ABSTRACT

A semiconductor structure and a preparation method thereof are provided. The semiconductor structure includes: a substrate; and a plurality of resistive devices disposed on the substrate; each of the resistive devices includes a lower electrode, a resistive layer and an upper electrode, the resistive layer covers a side wall and at least part of an upper surface of the lower electrode to isolate the lower electrode from the upper electrode, the upper electrode includes a first upper sub-electrode, a second upper sub-electrode and a third upper sub-electrode, the first upper sub-electrode and the second upper sub-electrode are disposed on two sides of the lower electrode respectively, and the third upper sub-electrode is disposed on the lower electrode.

### CROSS-REFERENCE TO THE RELATED APPLICATIONS

This application is based upon and claims priority to Chinese Patent Application No. 202311485763.5, filed on Nov. 9, 2023, the entire contents of which are incorporated herein by reference.

### TECHNICAL FIELD

The present disclosure relates to the technical field of semiconductors, and in particular to a semiconductor structure and a preparation method thereof.

### BACKGROUND

A resistive random access memory (RRAM) is a non-volatile memory for storing information by using the variable resistance characteristic of a material, and has the advantages of low power consumption, high density, high read-write speed, high durability and the like.

The existing RRAM has a 2T2R structure, that is, one transistor controls one resistive device (also called resistive switching device), resulting in a low integration level; furthermore, in the related art, the size of a resistive region (also called resistive switching region) is determined by the size of the resistive device, so it is difficult to miniaturize the size and provide an integration level.

### SUMMARY

The present disclosure provides a semiconductor structure and a preparation thereof, so as to at least solve the above technical problems in the related art.

According to a first aspect of the present disclosure, a semiconductor structure is provided and includes:
a substrate; and
a plurality of resistive devices disposed on the substrate; each of the resistive devices includes a lower electrode, a resistive layer and an upper electrode; the resistive layer (also called resistive switching layer) covers a side wall and at least part of an upper surface of the lower electrode to isolate the lower electrode from the upper electrode; the upper electrode includes a first upper sub-electrode, a second upper sub-electrode and a third upper sub-electrode, the first upper sub-electrode and the second upper sub-electrode are respectively disposed on two sides of the lower electrode, and the third upper sub-electrode is disposed on the lower electrode.

In an embodiment, upper surfaces of the first upper sub-electrode and the second upper sub-electrode may be lower than or flush with the upper surface of the lower electrode.

In an embodiment, a plurality of resistive devices may be arranged in an array in a first direction and a second direction, the first direction and the second direction may be parallel to a plane of the substrate, and the first direction may intersect with the second direction;
the first upper sub-electrode and the second upper sub-electrode respectively disposed on two sides of the lower electrode may include: the first upper sub-electrode and the second upper sub-electrode are respectively disposed on the two sides of the lower electrode in the first direction; and
the semiconductor structure may further include: a plurality of upper metal layers arranged in the first direction and extending in the second direction, the upper metal layers are disposed on the upper electrode, and each of the upper metal layers is electrically connected to each upper sub-electrode.

In an embodiment, the resistive layer covering the side wall and at least part of the upper surface of the lower electrode may include: the resistive layer covers part of the upper surface of the lower electrode; and
the size of a part of the resistive layer disposed on the upper surface of the lower electrode in the first direction may be equal to the size of the third upper sub-electrode in the first direction.

In an embodiment, the semiconductor structure may further include:
a lower metal layer disposed on the substrate; and the lower metal layer is electrically connected to the lower electrode.

According to a second aspect of the present disclosure, a preparation method for a semiconductor structure is provided. The method includes:
providing a substrate; and
forming a plurality of resistive devices on the substrate; each of the resistive devices includes a lower electrode, a resistive layer and an upper electrode, the resistive layer covers a side wall and at least part of an upper surface of the lower electrode to isolate the lower electrode from the upper electrode, the upper electrode includes a first upper sub-electrode, a second upper sub-electrode and a third upper sub-electrode, the first upper sub-electrode and the second upper sub-electrode are respectively disposed on two sides of the lower electrode, and the third upper sub-electrode is disposed on the lower electrode.

In an embodiment, the forming a plurality of resistive devices on the substrate may include:
forming the lower electrode on the substrate;
forming the resistive layer completely covering the side wall and the upper surface of the lower electrode;
respectively forming the first upper sub-electrode and the second upper sub-electrode on two sides of the resistive layer;
forming a first dielectric layer which covers upper surfaces of the first upper sub-electrode, the second upper sub-electrode and the resistive layer, and fills a gap between adjacent two first upper sub-electrode and second upper sub-electrode;
etching and removing part of the first dielectric layer disposed on the upper surface of the resistive layer to form a first groove; and
forming the third upper sub-electrode in the first groove.

In an embodiment, the forming a plurality of resistive devices on the substrate may include:
forming the lower electrode on the substrate;
forming the resistive layer completely covering the side wall and the upper surface of the lower electrode;
forming a first dielectric layer which covers upper surfaces of the first upper sub-electrode, the second upper sub-electrode and the resistive layer, and fills a gap between adjacent two first upper sub-electrode and second upper sub-electrode;
etching and removing the first dielectric layer disposed on the upper surfaces of the first upper sub-electrode, the second upper sub-electrode and the resistive layer, and the resistive layer disposed on the upper surface of the lower electrode;
forming a first resistive layer covering the first upper sub-electrode, the second upper sub-electrode and the lower electrode;
forming an initial third upper sub-electrode on the first resistive layer;
forming a third upper sub-electrode patterned mask on the initial third upper sub-electrode; and
using the third upper sub-electrode patterned mask to etch and remove the initial third upper sub-electrode and the first resistive layer which are not covered with the third upper sub-electrode patterned mask, retaining the initial third upper sub-electrode disposed on the lower electrode to form the third upper sub-electrode, and retaining the first resistive layer disposed below the third upper sub-electrode, the first resistive layer forming one part of the resistive layer.

In an embodiment, upper surfaces of the first upper sub-electrode and the second upper sub-electrode may be lower than or flush with the upper surface of the lower electrode.

In an embodiment, a plurality of resistive devices may be arranged in an array in a first direction and a second direction, the first direction and the second direction may be parallel to a plane of the substrate, and the first direction may intersect with the second direction;
the disposing the first upper sub-electrode and the second upper sub-electrode on two sides of the lower electrode respectively may include: the first upper sub-electrode and the second upper sub-electrode are respectively disposed on the two sides of the lower electrode in the first direction; and
the method may further include: forming a plurality of upper metal layers arranged in the first direction and extending in the second direction; the upper metal layers may be disposed on the upper electrode, and each of the metal layers may be electrically connected to each upper sub-electrode.

According to the semiconductor structure and the preparation method thereof provided by the present disclosure, the first upper sub-electrode and the second upper sub-electrode are formed on the two sides of the lower electrode, and the third upper sub-electrode is formed above the lower electrode, so that the device forms a 1T3R structure. The area of the resistive device in the related art is calculated according to the size of the plane, but in the present disclosure, the resistive device becomes a three-dimensional structure, the sizes of the first upper sub-electrode and the second upper sub-electrode on the two sides become the area of the side wall of the lower electrode, so the size of the resistive region can be changed by adjusting and controlling the height of the lower electrode, thereby increasing the integration level.

It should be understood that the content described in this section is not intended to identify critical or important features of the embodiments of the present disclosure, and is not used to limit the scope of the present disclosure either. Other features of the present disclosure will be easily understood through the following description.

### BRIEF DESCRIPTION OF THE DRAWINGS

By reading the following detailed description with reference to the accompanying drawings, the above and other objectives, features and advantages of the exemplary embodiments of the present disclosure will become easier to understand. In the drawings, several embodiments of the present disclosure are shown in an exemplary and non-limiting manner.

In the drawings, the same or corresponding reference numerals denote the same or corresponding parts.

FIG. 1 is a top view of a semiconductor structure according to an embodiment of the present disclosure.

FIG. 2 is a sectional view along a dotted line A-A′ direction in FIG. 1.

FIG. 3 is a sectional view along a dotted line B-B′ direction in FIG. 1.

FIG. 4 is a structural diagram of a semiconductor structure according to another embodiment of the present disclosure.

FIG. 5 is a structural diagram of a resistive device according to an embodiment of the present disclosure.

FIG. 6 is a flowchart of a preparation method for a semiconductor structure according to an embodiment of the present disclosure.

FIG. 7A to FIG. 7M are schematic diagrams of a semiconductor structure in the preparation process according to an embodiment of the present disclosure.

FIG. 8A to FIG. 8F are schematic diagrams of a semiconductor structure in the preparation process according to another embodiment of the present disclosure.

### DETAILED DESCRIPTION OF THE EMBODIMENTS

To make the objectives, features and advantages of the present disclosure apparent and easier to understand, the technical solutions in the embodiments of the present disclosure will be clearly and completely described below with reference to the accompanying drawings in the embodiments of the present disclosure. Apparently, the embodiments described are only some rather than all of the embodiments of the present disclosure. All other embodiments obtained by those skilled in the art based on the embodiments of the present disclosure without any creative efforts shall fall within the protection scope of the present disclosure.

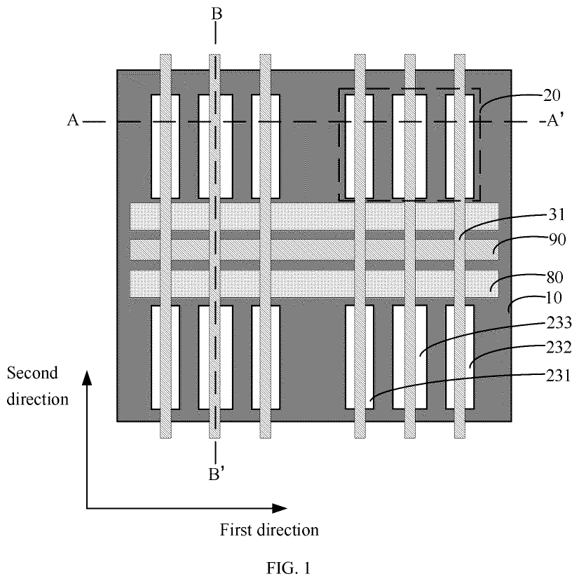

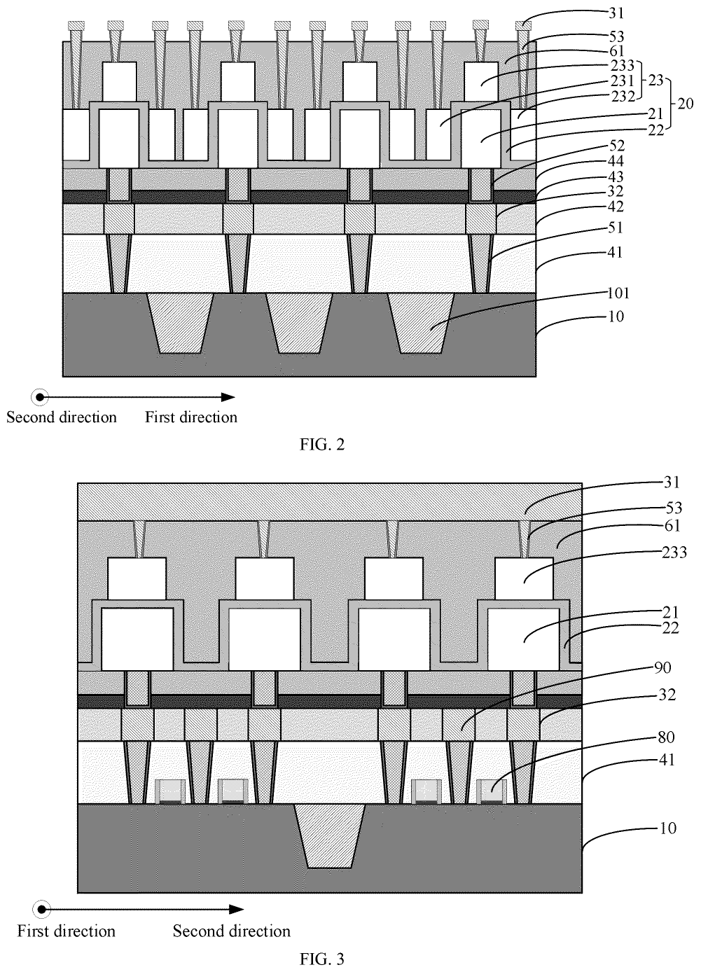

Embodiments of the present disclosure provide a semiconductor structure. FIG. 1 is a top view of a semiconductor structure according to an embodiment of the present disclosure; FIG. 2 is a sectional view along a dotted line A-A′ direction in FIG. 1; and FIG. 3 is a sectional view along a dotted line B-B′ direction in FIG. 1.

As shown in FIG. 2, the semiconductor structure includes:
a substrate 10; and
a plurality of resistive devices 20 disposed on the substrate 10; each of the resistive devices 20 includes a lower electrode 21, a resistive layer 22 and an upper electrode 23; the resistive layer 22 covers a side wall and at least part of an upper surface of the lower electrode 21 to isolate the lower electrode 21 from the upper electrode 23; the upper electrode 23 includes a first upper sub-electrode 231, a second upper sub-electrode 232 and a third upper sub-electrode 233, the first upper sub-electrode 231 and the second upper sub-electrode 232 are respectively disposed on two sides of the lower electrode 21, and the third upper sub-electrode 233 is disposed on the lower electrode 21.

In some embodiments, the substrate 10 may be an elemental semiconductor material substrate (such as a silicon substrate, a germanium substrate and the like), a composite semiconductor material substrate (such as a germanium-silicon substrate and the like), a silicon on insulator (SOI) substrate, a germanium on insulator (GOI) substrate and the like. A shallow groove isolating structure 101 is formed in the substrate 10.

In some embodiments, the semiconductor structure further includes: a first interlayer dielectric layer 41, a second interlayer dielectric layer 42, a third interlayer dielectric layer 43 and a fourth interlayer dielectric layer 44 which are sequentially stacked on the substrate 10.

A material of the first interlayer dielectric layer 41 includes, but is not limited to an insulating material such as silicon oxide, silicon nitride, silicon oxynitride and the like; the second interlayer dielectric layer 42 may be a metal interlayer dielectric layer, such as aluminum oxide, zinc oxide and the like; the third interlayer dielectric layer 43 may be a nitride doped silicon carbide (NDC) film; and a material of the fourth interlayer dielectric layer 44 includes, but is not limited to plasma enhanced oxide (PEOX) layer.

The semiconductor structure further includes: a first contact via 51 disposed in the first interlayer dielectric layer 41.

In an embodiment, the semiconductor structure further includes: a lower metal layer 32 disposed on the substrate 10, and the lower metal layer 32 is electrically connected to the lower electrode 21.

Specifically, as shown in FIG. 2, the lower metal layer 32 is disposed in the second interlayer dielectric layer 42, and is connected to the substrate 10 through the first contact via 51. A second contact via 52 is formed on the lower metal layer 32, the second contact via 52 penetrates through the third interlayer dielectric layer 43 and the fourth interlayer dielectric layer 44, and the lower metal layer 32 is electrically connected to the lower electrode 21 through the second contact via 52.

A material of the lower metal layer 32 includes, but is not limited to copper. The first contact via 51 and the second contact via 52 may be of a double-layer structure, and materials of the first contact via 51 and the second contact via 52 may include titanium nitride disposed on an outer layer and tungsten disposed on an inner layer.

As shown in FIG. 3, the semiconductor structure further includes: a grid electrode structure 80 disposed in the first interlayer dielectric layer 41, and the grid electrode structure 80 includes a grid dielectric layer and a grid electrode conductive layer disposed on the grid dielectric layer. A side wall of the grid electrode structure 80 is also covered with a side wall structure (not shown in figures).

As shown in FIG. 3, the semiconductor structure further includes: a source electrode wire 90 disposed in the second interlayer dielectric layer 42, and the source electrode wire 90 may also be connected to the substrate 10 through the contact via.

The resistive devices 20 are disposed on the fourth interlayer dielectric layer 44, and each of the resistive devices 20 includes the lower electrode 21, the resistive layer 22 and the upper electrode 23.

A material of the lower electrode 21 includes, but is not limited to titanium nitride. A material of the resistive layer 22 includes transition metal oxide, specifically, for example, hafnium oxide, aluminum oxide and the like. A material of the upper electrode 23 includes, but is not limited to titanium nitride.

As shown in FIG. 1, a plurality of resistive devices 20 are arranged in an array in a first direction and a second direction, the first direction and the second direction are parallel to a plane of the substrate, and the first direction intersects with the second direction.

The resistive layer 22 covers the side wall and at least part of the upper surface of the lower electrode 21 so as to isolate the lower electrode 21 from the upper electrode 23.

In some embodiments, as shown in FIG. 2, the resistive layer 22 completely covers the side wall and the upper surface of the lower electrode 21, so that the lower electrode and the upper electrode can be isolated better, and short circuit between the lower electrode and the upper electrode can be avoided.

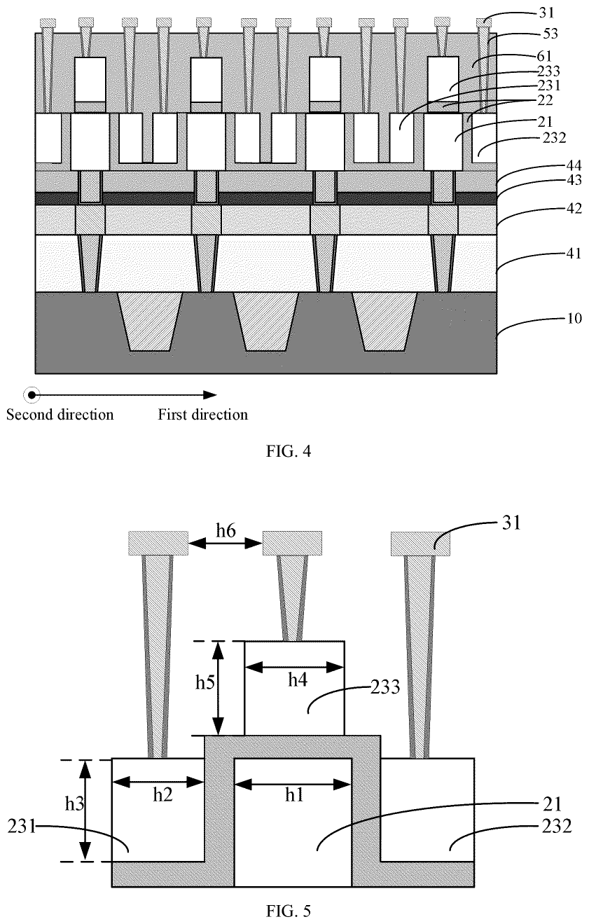

In some other embodiments, as shown in FIG. 4, the resistive layer 22 covers part of the upper surface of the lower electrode 21; and the size of a part of the resistive layer 22 disposed on the upper surface of the lower electrode 21 in the first direction is equal to the size of the third upper sub-electrode 233 in the first direction. In this embodiment, in the process of forming the third upper sub-electrode and the resistive layer, both the third upper sub-electrode and the resistive layer can be formed together through a one-step process, thereby reducing the process steps.

The upper electrode 23 includes the first upper sub-electrode 231, the second upper sub-electrode 232 and the third upper sub-electrode 233.

As shown in FIG. 2, the first upper sub-electrode 231 and the second upper sub-electrode 232 are respectively disposed on two sides of the lower electrode 21, which includes: the first upper sub-electrode 231 and the second upper sub-electrode 232 are respectively disposed on the two sides of the lower electrode 21 in the first direction.

The third upper sub-electrode 233 is disposed above the lower electrode 21. The size of the third upper sub-electrode 233 is less than the size of the lower electrode 21. In an embodiment, the size of the third upper sub-electrode 233 is 40-45 nm less than the size of the lower electrode 21, preferably, 43 nm, thereby avoiding short circuit due to the third upper sub-electrode in contact with the first upper sub-electrode and the second upper sub-electrode caused by yellow light overlay (alignment control) drift.

In an embodiment, upper surfaces of the first upper sub-electrode 231 and the second upper sub-electrode 232 are lower than or flush with the upper surface of the lower electrode 21.

If the upper surfaces of the first upper sub-electrode and the second upper sub-electrode are higher than the upper surface of the lower electrode, the first upper sub-electrode and the second upper sub-electrode may be in contact with the third upper sub-electrode to cause short circuit, thereby affecting the performance of the device. Therefore, the upper surfaces of the first upper sub-electrode and the second upper sub-electrode are set to be lower than or flush with the upper surface of the lower electrode, so that the first upper sub-electrode and the second upper sub-electrode can be isolated from the third upper sub-electrode better.

FIG. 5 is a structural diagram of a resistive device according to an embodiment of the present disclosure. As shown in FIG. 5, in an embodiment, the width h1 of the lower electrode 21 may be 173 nm, and the first upper sub-electrode 231 and the second upper sub-electrode 232 have the same structure size; and in an embodiment, the width h2 may be 80 nm, and the height h3 may be 130 nm, which may be understood that the heights of the first upper sub-electrode 231 and the second upper sub-electrode 232 can be changed by adjusting and controlling the height of the lower electrode 21, thereby adjusting and controlling the size of a resistive region and increasing the integration level. In an embodiment, the width h4 of the third upper sub-electrode 233 may be 130 nm, and the height h5 may be 80 nm.

The size of the 2T2R structure in the width direction in the related art is 345 nm, and according to the area, the present disclosure may achieve a 1T3R structure. Compared with the related art, one resistive device may be added. In addition, the size of a storage unit in the related art is 55.6 F², and the size of a storage unit in the present disclosure is 37.0 F², so the present disclosure can achieve a higher storage density.

In an embodiment, the semiconductor structure further includes: a first dielectric layer 61; the first dielectric layer 61 covers the upper surfaces of the first upper sub-electrode 231, the second upper sub-electrode 232 and the third upper sub-electrode 233, and fills a gap between adjacent two first upper sub-electrode 231 and second upper sub-electrode 232.

A material of the first dielectric layer 61 includes an insulating material such as silicon oxide, silicon nitride, silicon oxynitride and the like.

In an embodiment, the semiconductor structure further includes: a plurality of upper metal layers 31 arranged in the first direction and extending in the second direction, the upper metal layers 31 are disposed on the upper electrode 23, and each of the upper metal layers 31 is electrically connected to each upper sub-electrode.

Specifically, as shown in FIG. 2, the first upper sub-electrode 231, the second upper sub-electrode 232 and the third upper sub-electrode 233 are respectively connected to one upper metal layer 31.

The upper metal layer 31 is connected to each upper sub-electrode through a third contact via 53, and the third contact via 53 is partially disposed in the first dielectric layer 61.

As shown in FIG. 5, in an embodiment, the distance h6 between the adjacent two upper metal layers 31 may be 50 nm, and the width of each of the upper metal layers 31 may be 80 nm.

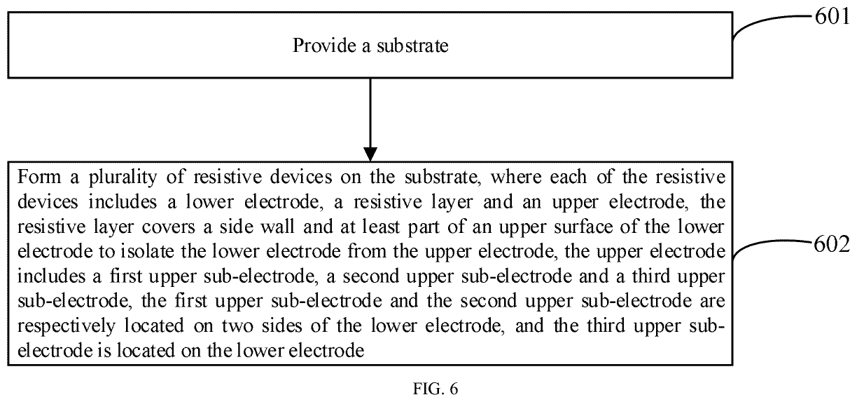

Embodiments of the present disclosure further provide a preparation method for a semiconductor structure. FIG. 6 is a flowchart of a preparation method for a semiconductor structure according to an embodiment of the present disclosure. Referring to FIG. 6, the method includes the following steps:

Step 601: a substrate is provided; and

Step 602: a plurality of resistive devices are formed on the substrate; each of the resistive devices includes a lower electrode, a resistive layer and an upper electrode, the resistive layer covers a side wall and at least part of an upper surface of the lower electrode to isolate the lower electrode from the upper electrode, the upper electrode includes a first upper sub-electrode, a second upper sub-electrode and a third upper sub-electrode, the first upper sub-electrode and the second upper sub-electrode are respectively disposed on two sides of the lower electrode, and the third upper sub-electrode is disposed on the lower electrode.

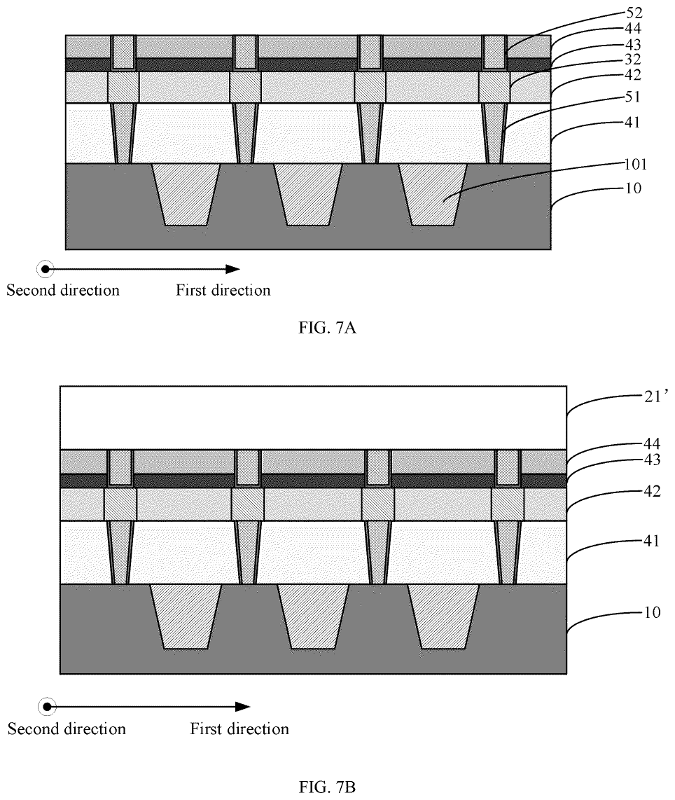

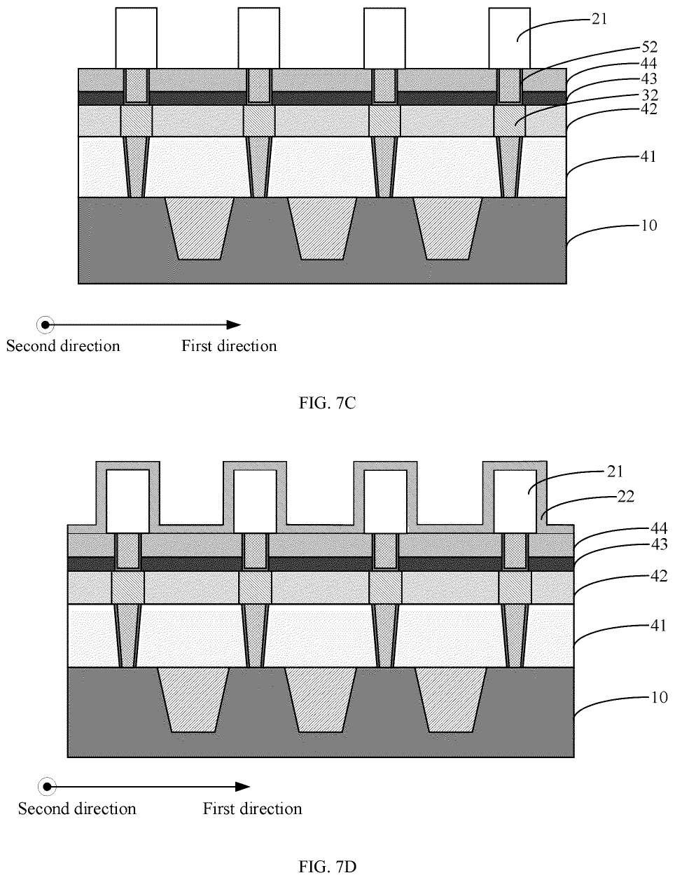

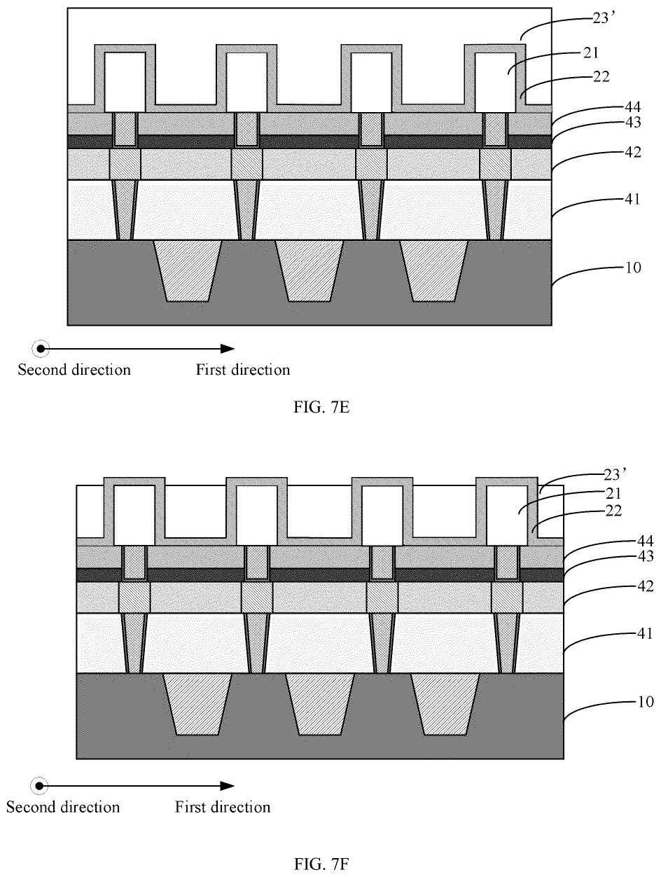

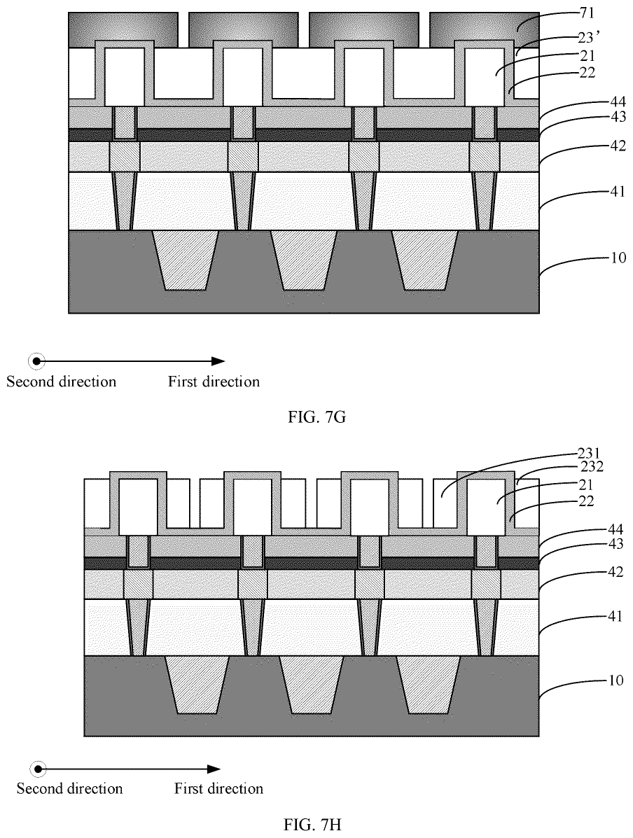

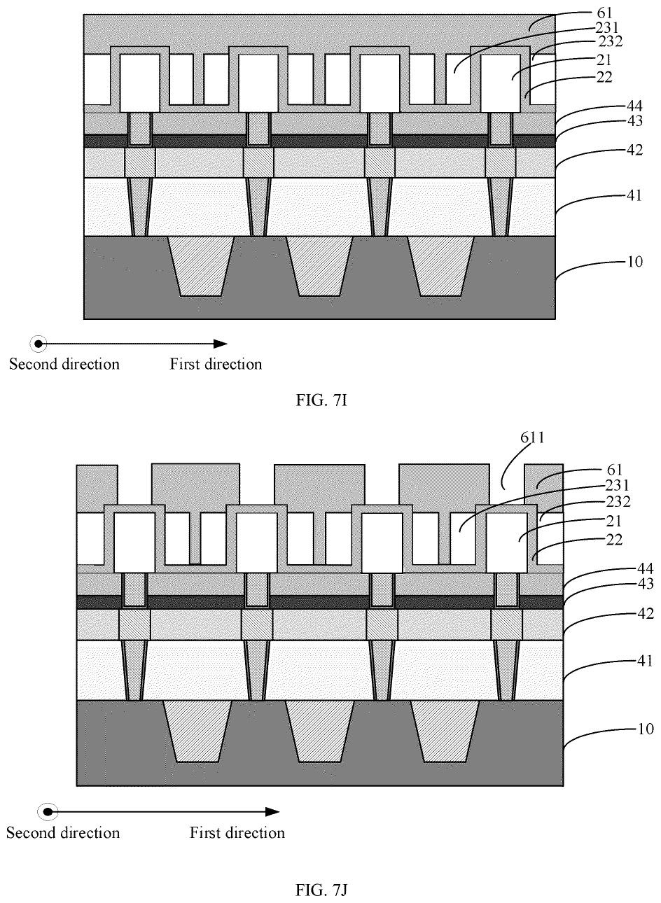

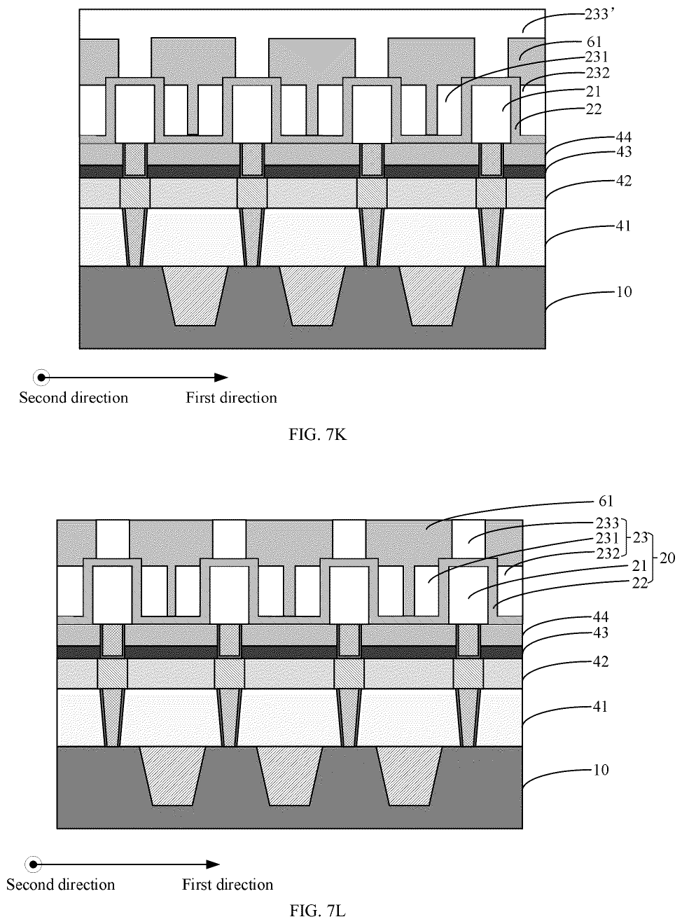

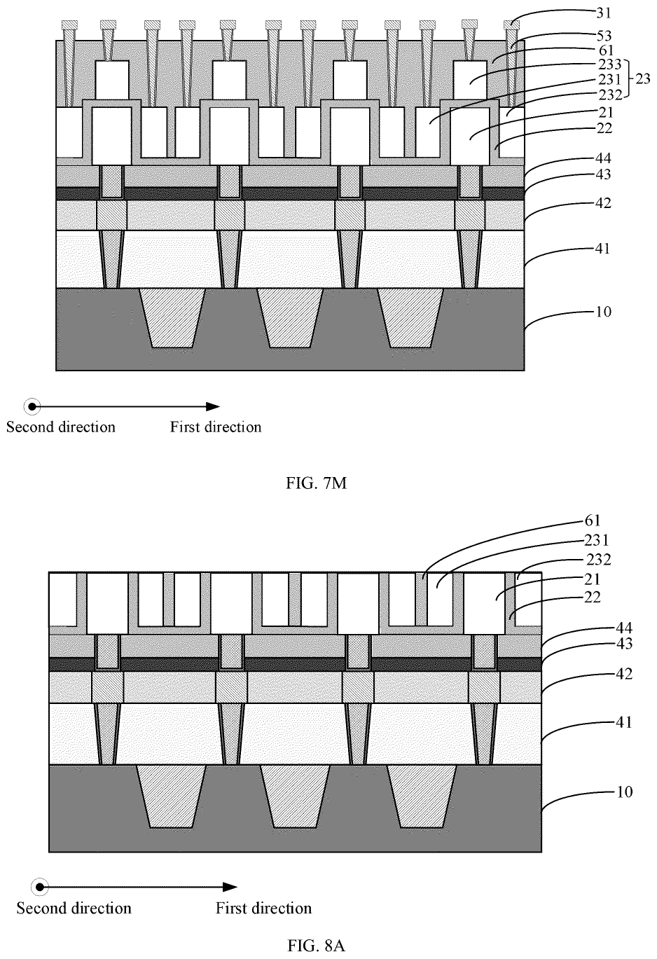

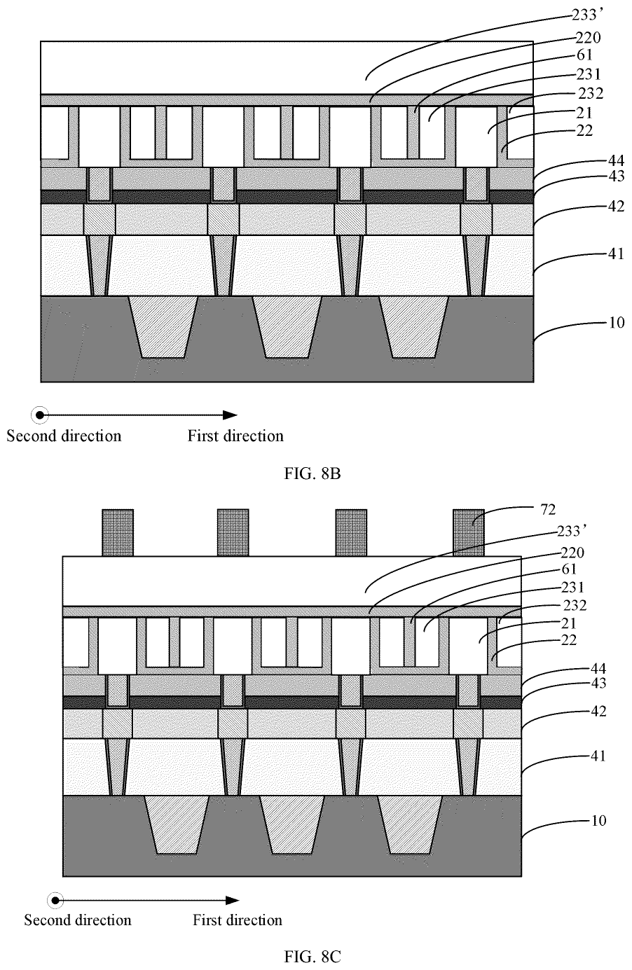

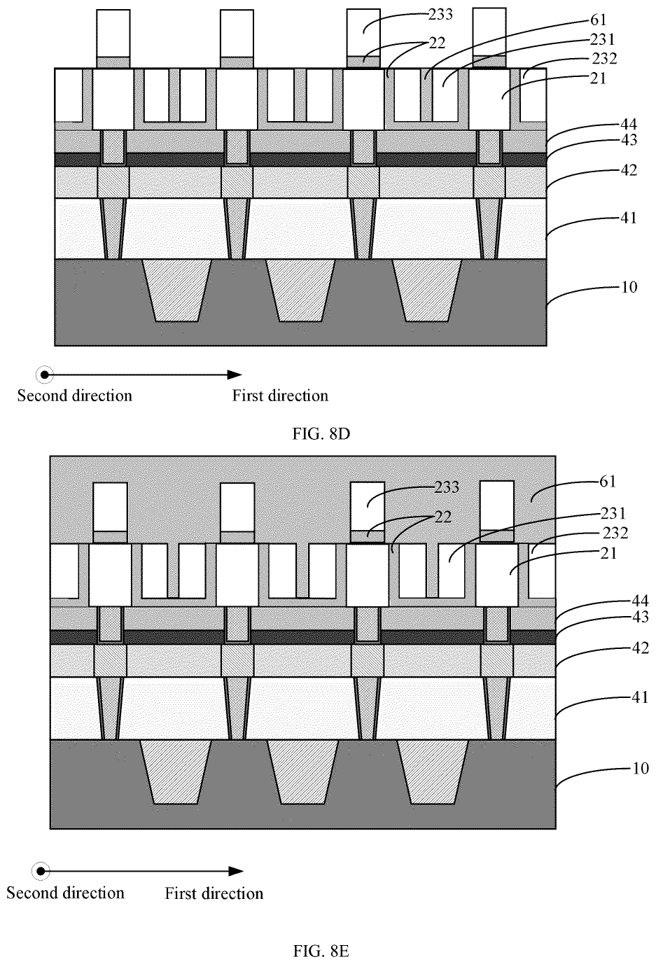

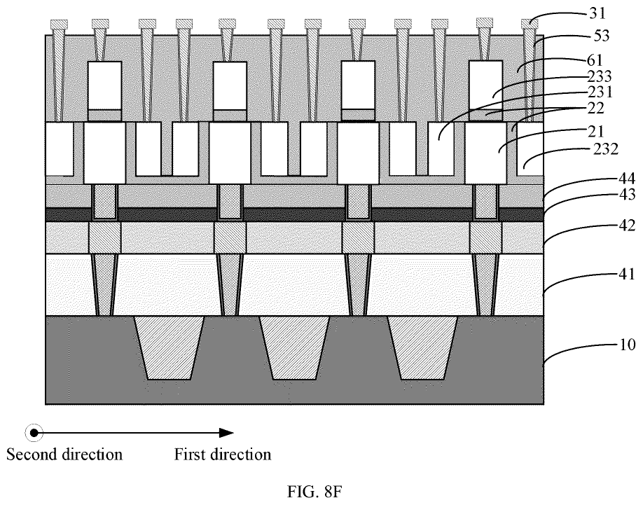

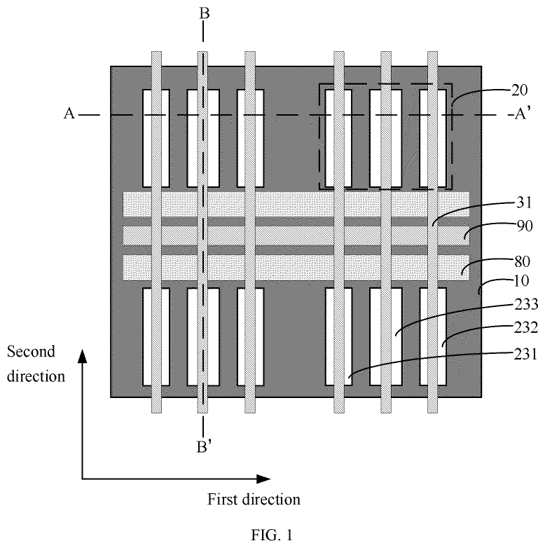

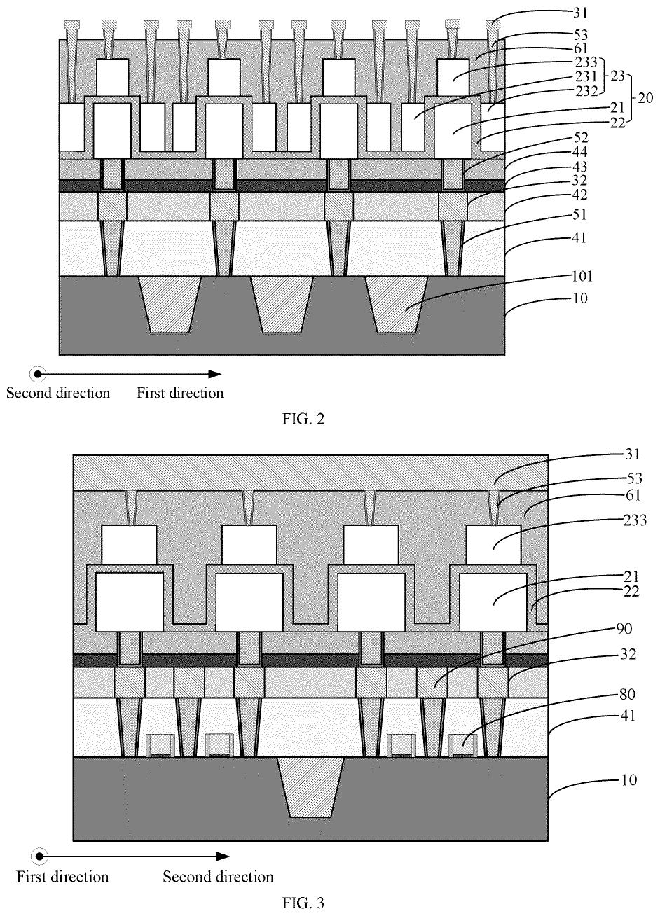

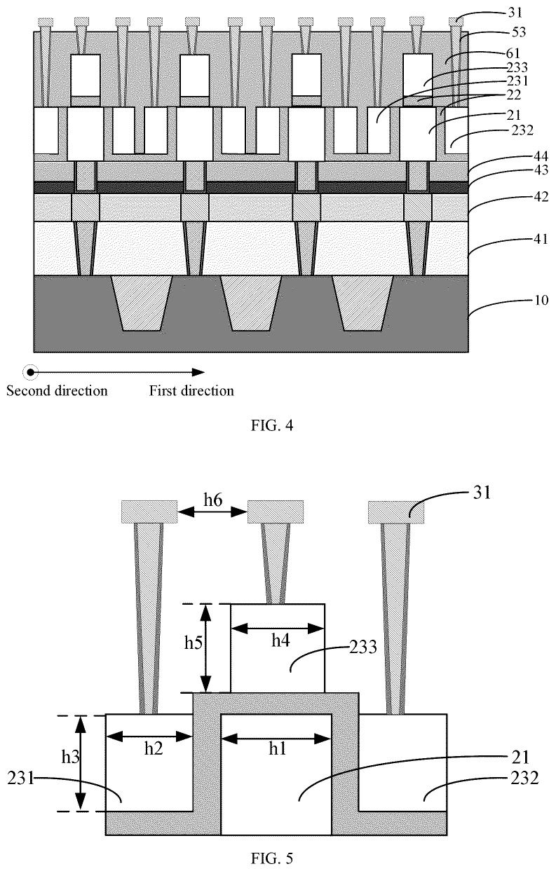

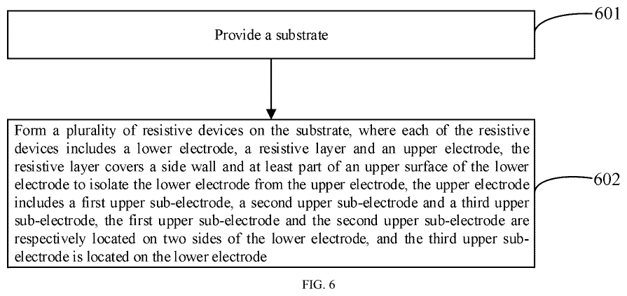

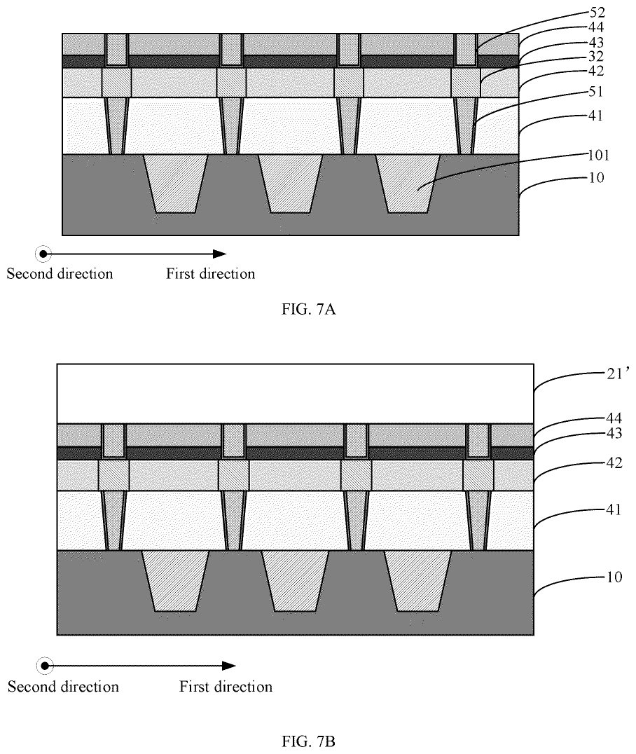

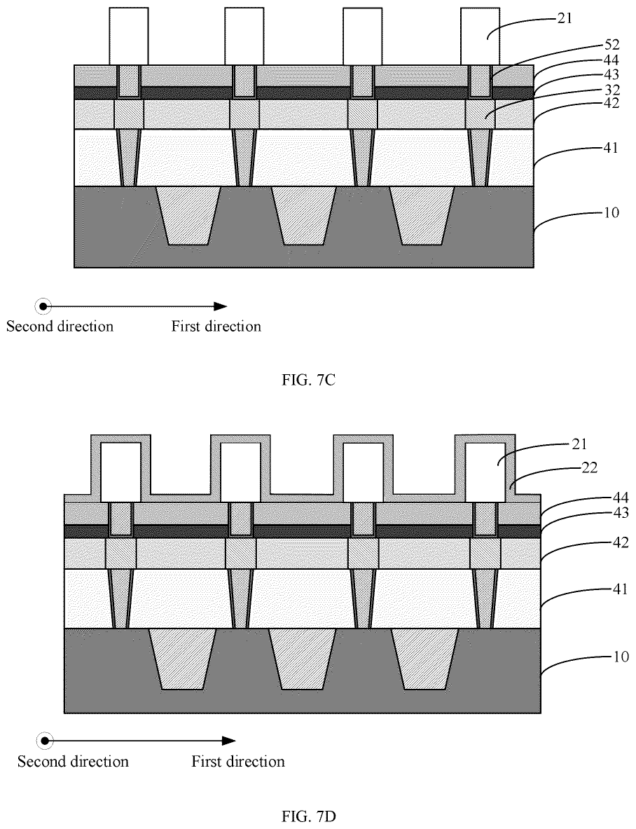

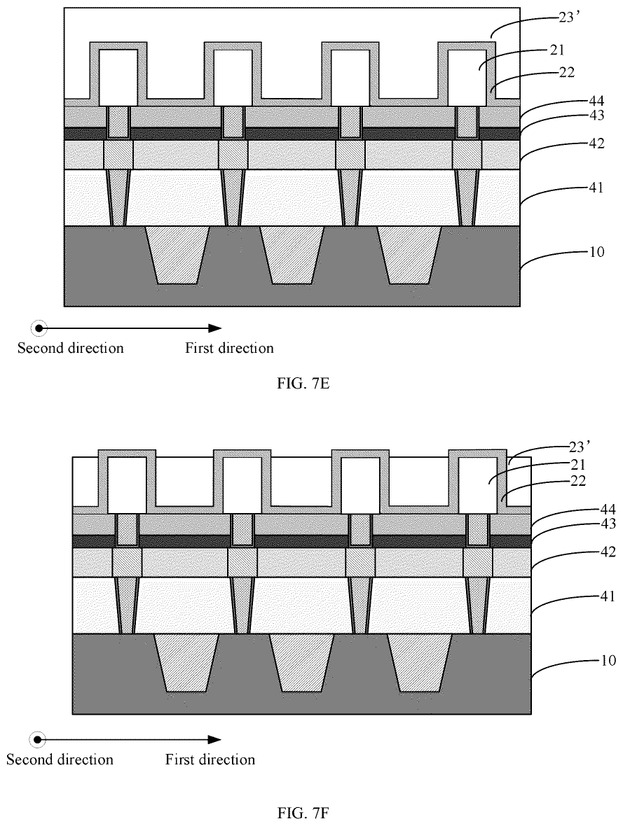

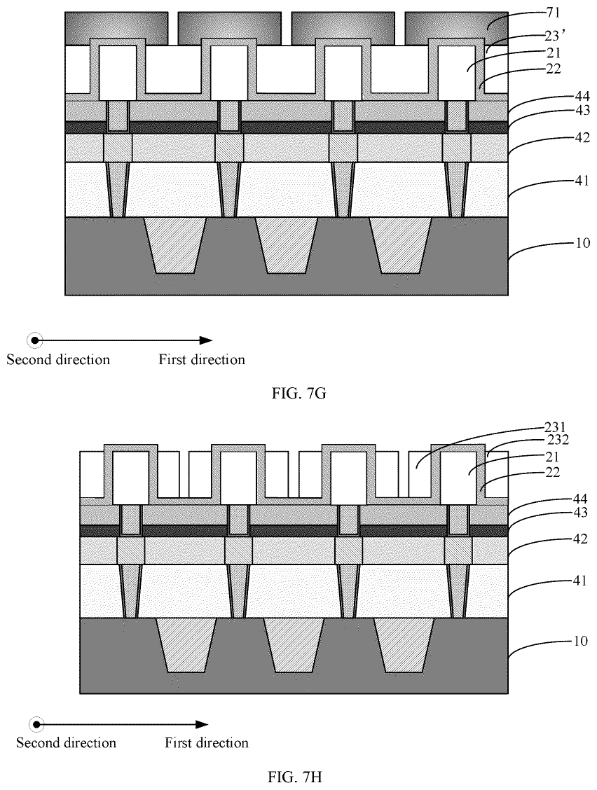

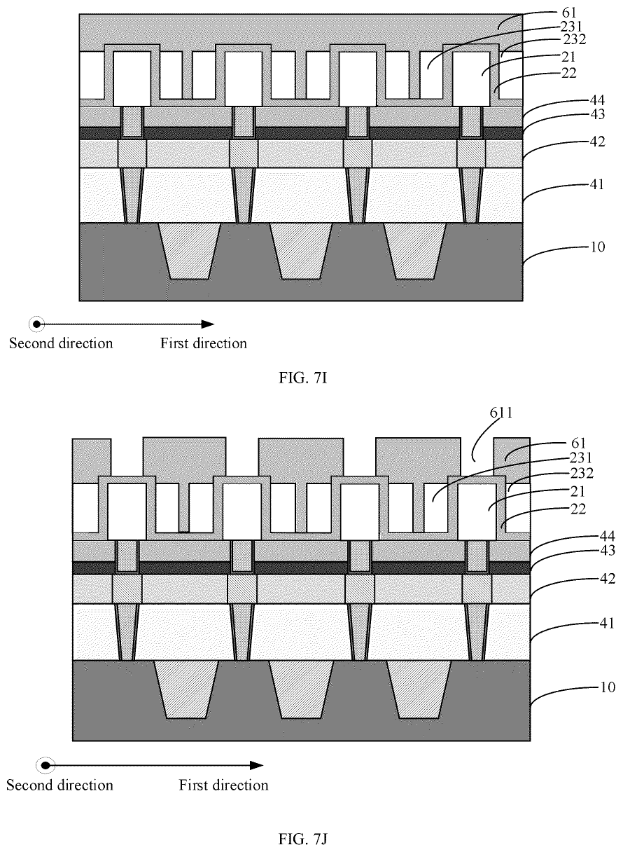

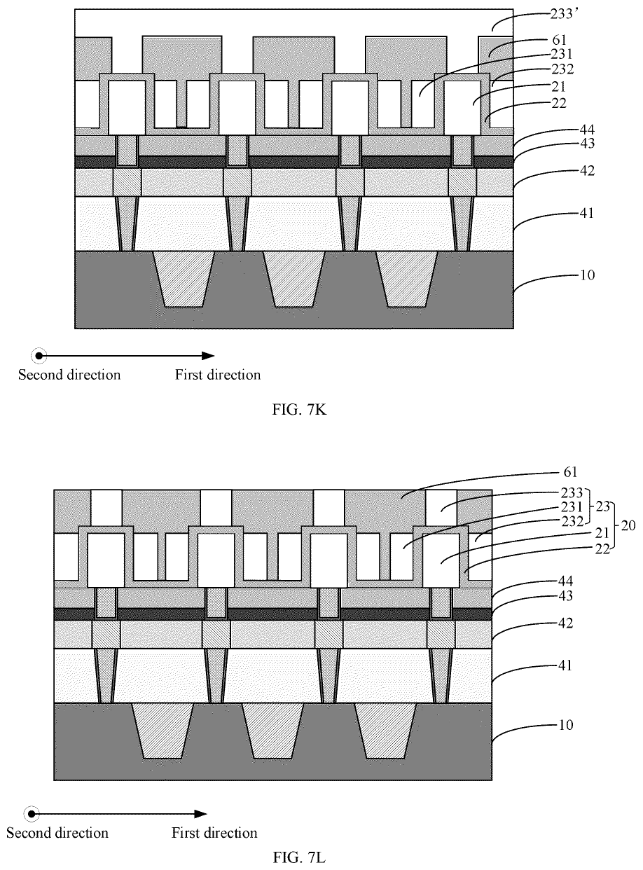

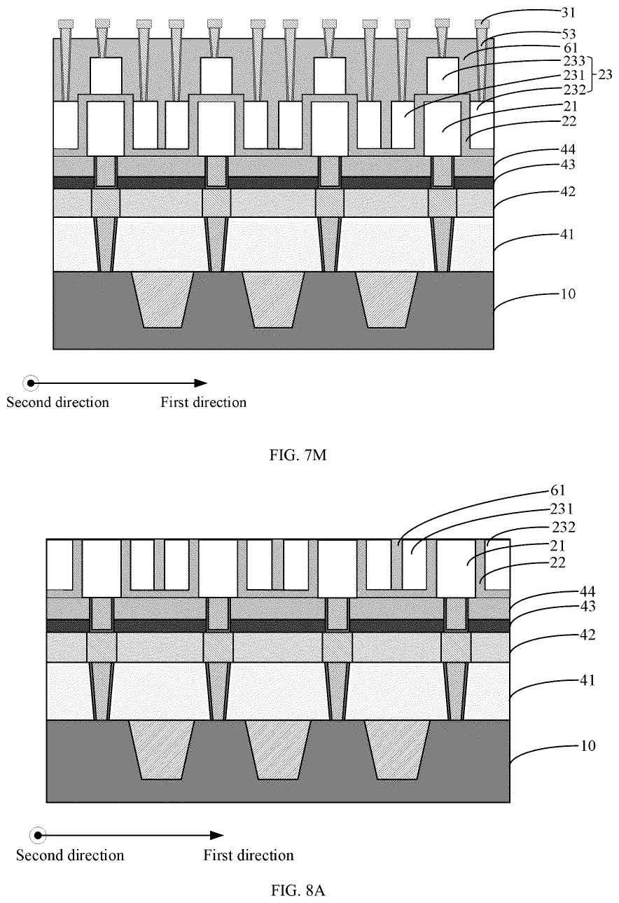

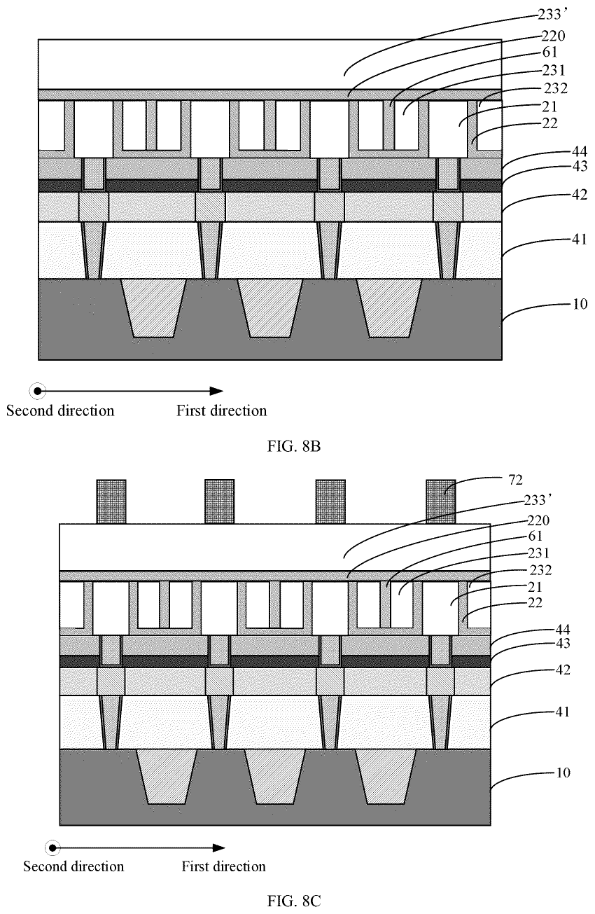

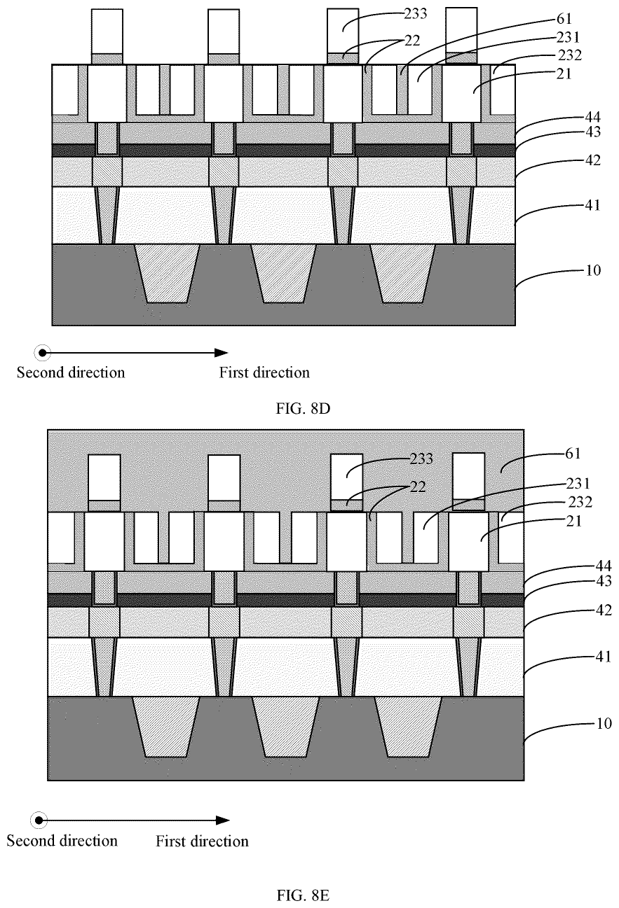

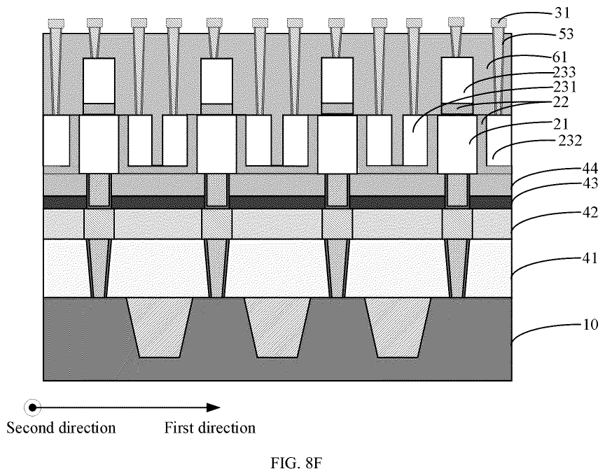

The preparation method for the semiconductor structure provided by the embodiments of the present disclosure is further described below in detail in combination with specific embodiments. FIG. 7A to FIG. 7M are schematic diagrams of a semiconductor structure in the preparation process according to an embodiment of the present disclosure. FIG. 8A to FIG. 8F are schematic diagrams of a semiconductor structure in the preparation process according to another embodiment of the present disclosure.

Then, the embodiments shown in FIG. 7A to FIG. 7M are described in detail.

First, referring to FIG. 7A, the step 601 is performed. The substrate 10 is provided.

In an embodiment, the substrate 10 may be an elemental semiconductor material substrate (such as a silicon substrate, a germanium substrate and the like), a composite semiconductor material substrate (such as a germanium-silicon substrate and the like), a silicon on insulator (SOI) substrate, a germanium on insulator (GOI) substrate and the like.

A shallow groove isolating structure 101 is formed in the substrate 10.

Continuously referring to FIG. 7A, a first interlayer dielectric layer 41, a second interlayer dielectric layer 42, a third interlayer dielectric layer 43 and a fourth interlayer dielectric layer 44 are sequentially formed on the substrate 10.

In actual operation, the first interlayer dielectric layer 41, the second interlayer dielectric layer 42, the third interlayer dielectric layer 43 and the fourth interlayer dielectric layer 44 may be formed through chemical vapor deposition (CVD), physical vapor deposition (PVD), atomic layer deposition (ALD) or other deposition methods.

A material of the first interlayer dielectric layer 41 includes, but is not limited to an insulating material such as silicon oxide, silicon nitride, silicon oxynitride and the like; the second interlayer dielectric layer 42 may be a metal interlayer dielectric layer, such as aluminum oxide, zinc oxide and the like; the third interlayer dielectric layer 43 may be a nitride doped silicon carbide (NDC) film; and a material of the fourth interlayer dielectric layer 44 includes, but is not limited to plasma enhanced oxide (PEOX) layer.

Continuously referring to FIG. 7A, a first contact via 51 is formed in the first interlayer dielectric layer 41; a lower metal layer 32 is formed in the second interlayer dielectric layer 42; and the lower metal layer 32 is disposed on the first contact via 51 and connected to the substrate 10 through the first contact via 51.

A second contact via 52 is formed in the third interlayer dielectric layer 43 and the fourth interlayer dielectric layer 44; the second contact via 52 is disposed on the lower metal layer 32; and the lower metal layer 32 is electrically connected to the subsequently formed lower electrode 21 through the second contact via 52.

A material of the lower metal layer 32 includes, but is not limited to copper. The first contact via 51 and the second contact via 52 may be of a double-layer structure, and materials of the first contact via 51 and the second contact via 52 may include titanium nitride disposed on an outer layer and tungsten disposed on an inner layer.

In an embodiment, referring to FIG. 3, a grid electrode structure 80 is formed in the first interlayer dielectric layer 41, and the grid electrode structure 80 includes a grid dielectric layer and a grid electrode conductive layer disposed on the grid dielectric layer. A side wall of the grid electrode structure 80 is also covered with a side wall structure (not shown in figures).

Continuously referring to FIG. 3, a source electrode wire 90 is formed in the second interlayer dielectric layer 42, and the source electrode wire 90 may also be connected to the substrate 10 through the contact via.

In an embodiment, referring to FIG. 7B to FIG. 7L, the forming a plurality of resistive devices 20 on the substrate 10 includes:
the lower electrode 21 is formed on the substrate 10;
the resistive layer 22 completely covering the side wall and the upper surface of the lower electrode 21 is formed;
the first upper sub-electrode 231 and the second upper sub-electrode 232 are respectively formed on two sides of the resistive layer 22;
a first dielectric layer 61 is formed; the first dielectric layer 61 covers upper surfaces of the first upper sub-electrode 231, the second upper sub-electrode 232 and the resistive layer 22, and fills a gap between adjacent two first upper sub-electrode 231 and second upper sub-electrode 232;
part of the first dielectric layer 61 disposed on the upper surface of the resistive layer 22 is etched and removed to form a first groove 611; and
the third upper sub-electrode 233 is formed in the first groove 611.

Specifically, referring to FIG. 7B, an initial lower electrode 21′ is formed on the fourth interlayer dielectric layer 44.

Referring to FIG. 7C, part of the initial lower electrode 21′ is etched and removed to form the lower electrode 21.

Specifically, a mask layer may be formed on the initial lower electrode 21′, then the mask layer is patterned through photoetching to form a lower electrode pattern on the mask layer, and etching is performed according to the lower electrode pattern on the mask layer to form the lower electrode 21.

A material of the lower electrode 21 includes, but is not limited to titanium nitride.

An etching process may be wet etching process, or may be a dry etching process, preferably, the dry etching process. The dry etching process includes, but is not limited to at least one of ion milling etching, plasma etching, reactive ion etching or laser ablation.

Then, referring to FIG. 7D, the resistive layer 22 is formed; the resistive layer 22 completely covers the side wall and the upper surface of the lower electrode 21, and also covers the surface of the fourth interlayer dielectric layer 44.

In this embodiment, the resistive layer completely covers the upper surface of the lower electrode. In this way, the lower electrode and the upper electrode can be isolated better, and short circuit between the lower electrode and the upper electrode can be avoided.

A material of the resistive layer 22 includes transition metal oxide, specifically, for example, hafnium oxide, aluminum oxide and the like.

Referring to FIG. 7E, an initial upper electrode 23′ covering the resistive layer 22 is formed.

Referring to FIG. 7F, part of the initial upper electrode 23′ is etched and removed, so that an upper surface of the remaining initial upper electrode 23 is lower than or flush with the upper surface of the lower electrode 21.

If the upper surface of the remaining initial upper electrode is higher than the upper surface of the lower electrode, the subsequently formed first upper sub-electrode and second upper sub-electrode may be in contact with the third upper sub-electrode to cause short circuit, thereby affecting the performance of the device. Therefore, the upper surface of the remaining initial upper electrode is lower than or flush with the upper surface of the lower electrode, so that the first upper sub-electrode and the second upper sub-electrode can be isolated from the third upper sub-electrode better.

In actual operation, part of the initial upper electrode 23′ may be removed through dry etching or wet etching. In a preferred embodiment, wet etching may be used because wet etching can be controlled by seconds, so that the upper surface of the remaining initial upper electrode 23′ is lower than or flush with the upper surface of the lower electrode 21.

Referring to FIG. 7G and FIG. 7H, the first upper sub-electrode 231 and the second upper sub-electrode 232 are respectively formed on the two sides of the resistive layer 22.

Specifically, a patterned mask 71 is formed on the resistive layer 22 and the initial upper electrode 23′, and part of the initial upper electrode 23′ between the adjacent two lower electrodes 21 is etched and removed by using the patterned mask 71, so that the initial upper electrode 23′ between the adjacent two lower electrodes 21 is cut off, and two independent upper sub-electrodes are formed. The two upper sub-electrodes are the first upper sub-electrode 231 and the second upper sub-electrode 232 of the adjacent two resistive devices respectively.

The first upper sub-electrode 231 and the second upper sub-electrode 232 are formed by the remaining initial upper electrode 23′, so the upper surfaces of the first upper sub-electrode 231 and the second upper sub-electrode 232 are lower than or flush with the upper surface of the lower electrode 21.

Then, referring to FIG. 7I, the first dielectric layer 61 is formed; the first dielectric layer 61 covers the upper surfaces of the first upper sub-electrode 231, the second upper sub-electrode 232 and the resistive layer 22, and fills the gap between the adjacent two first upper sub-electrodes 231 and second upper sub-electrodes 232.

A material of the first dielectric layer 61 includes an insulating material such as silicon oxide, silicon nitride, silicon oxynitride and the like.

Referring to FIG. 7J, part of the first dielectric layer 61 disposed on the upper surface of the resistive layer 22 is etched and removed to form the first groove 611.

Specifically, a mask layer may be formed on the first dielectric layer 61, then the mask layer is patterned through photoetching to form a first groove position disposed on the mask layer; according to the first groove position, the first dielectric layer 61 is etched to transfer the first groove position into the first dielectric layer 61 to form the first groove 611.

In this step, the same photomask as used when the lower electrode 21 is formed may be used, so that the increased use of the photomask can be avoided.

Then, referring to FIG. 7K and FIG. 7L, the third upper sub-electrode 233 is formed in the first groove 611.

Specifically, an initial third upper sub-electrode 233′ covering the first dielectric layer 61 and filing the first groove 611 is formed first, and then the initial third upper sub-electrode 233′ disposed on the first dielectric layer 61 is removed through a chemical mechanical polishing (CMP) process so as to form the third upper sub-electrode 233 disposed in the first groove 611, thereby forming the whole resistive device 20.

A material of the upper electrode 23 includes, but is not limited to titanium nitride.

In this embodiment, the first upper sub-electrode, the second upper sub-electrode and the third upper sub-electrode are made separately, so this may cause the sizes of the first upper sub-electrode and the second upper sub-electrode on the left and right side to be different from the size of the third upper sub-electrode above. However, in the etching process of the resistive device, according to the actual measurement result, the size difference of the resistive devices in a wafer face may be about 7 nm; and according to a relationship between the size of the resistive device collected and the forming voltage, the size difference of the resistive devices is 20 nm, and the difference of the forming voltages is only 0.1V, so the poor uniformity caused by the separate manufacturing of the first upper sub-electrode, the second upper sub-electrode and the third upper sub-electrode has little effect on the electrical property.

As shown in FIG. 1, a plurality of resistive devices 20 are arranged in an array in a first direction and a second direction, the first direction and the second direction are parallel to a plane of the substrate 10, and the first direction intersects with the second direction.

The first upper sub-electrode 231 and the second upper sub-electrode 232 are respectively disposed on two sides of the lower electrode 21, which includes: the first upper sub-electrode 231 and the second upper sub-electrode 232 are respectively disposed on the two sides of the lower electrode 21 in the first direction.

Then, referring to FIG. 7M, one layer of dielectric material is continuously deposited, so that the first dielectric layer 61 covers the third upper sub-electrode 233.

Continuously referring to FIG. 7M, a plurality of upper metal layers 31 arranged in the first direction and extending in the second direction are formed; the upper metal layers 31 are disposed on the upper electrode 23, and each of the metal layers 31 is electrically connected to each upper sub-electrode.

Specifically, as shown in FIG. 7M, the first upper sub-electrode 231, the second upper sub-electrode 232 and the third upper sub-electrode 233 are respectively connected to one upper metal layer 31.

The upper metal layer 31 is connected to each upper sub-electrode through a third contact via 53, and the third contact via 53 is partially disposed in the first dielectric layer 61.

Then, the embodiments shown in FIG. 8A to FIG. 8F are described in detail. It should be noted that the steps before FIG. 8A are the same as those in FIG. 7A to FIG. 7I.

In an embodiment, the forming a plurality of resistive devices 20 on the substrate 10 includes:
the lower electrode 21 is formed on the substrate 10;
the resistive layer 22 completely covering the side wall and the upper surface of the lower electrode 21 is formed;
a first dielectric layer 61 is formed; the first dielectric layer 61 covers upper surfaces of the first upper sub-electrode 231, the second upper sub-electrode 232 and the resistive layer 22, and fills a gap between adjacent two first upper sub-electrode 231 and second upper sub-electrode 232;
the first dielectric layer 61 disposed on the upper surfaces of the first upper sub-electrode 231, the second upper sub-electrode 232 and the resistive layer 22, and the resistive layer 22 disposed on the upper surface of the lower electrode 21 are etched and removed;
a first resistive layer 220 covering the first upper sub-electrode 231, the second upper sub-electrode 232 and the lower electrode 21 is formed;
an initial third upper sub-electrode 233′ is formed on the first resistive layer 220;
a third upper sub-electrode patterned mask 72 is formed on the initial third upper sub-electrode 233′; and
the third upper sub-electrode patterned mask 72 is used to etch and remove the initial third upper sub-electrode 233′ and the first resistive layer 220 which are not covered with the third upper sub-electrode patterned mask 72, the initial third upper sub-electrode 233′ disposed on the lower electrode 21 is retained to form the third upper sub-electrode 233, and the first resistive layer 220 disposed below the third upper sub-electrode 233 is retained; the first resistive layer forms one part of the resistive layer 22.

In this embodiment, the steps before FIG. 8A, that is, the steps before the first dielectric layer 61 is formed are the same as those in FIG. 7A to FIG. 7I, so the steps are not described in detail herein.

Referring to FIG. 8A, the first dielectric layer 61 disposed on the upper surfaces of the first upper sub-electrode 231, the second upper sub-electrode 232 and the resistive layer 22, and the resistive layer 22 disposed on the upper surface of the lower electrode 21 are etched and removed.

Referring to FIG. 8B, the first resistive layer 220 covering the first upper sub-electrode 231, the second upper sub-electrode 232 and the lower electrode 21 is formed; and the initial third upper sub-electrode 233′ is formed on the first resistive layer 220.

In actual operation, the first resistive layer 220 and the initial third upper sub-electrode 233′ may be formed through chemical vapor deposition (CVD), physical vapor deposition (PVD), atomic layer deposition (ALD) or other deposition methods.

Referring to FIG. 8C, the third upper sub-electrode patterned mask 72 is formed on the initial third upper sub-electrode 233′.

Referring to FIG. 8D, the third upper sub-electrode patterned mask 72 is used to etch and remove the initial third upper sub-electrode 233′ and the first resistive layer 220 which are not covered with the third upper sub-electrode patterned mask 72, the initial third upper sub-electrode 233′ disposed on the lower electrode 21 is retained to form the third upper sub-electrode 233, and the first resistive layer 220 disposed below the third upper sub-electrode 233 is retained; the first resistive layer 220 forms one part of the resistive layer 22.

In this step, the third upper sub-electrode 233 and the retained first resistive layer 220 are formed in the same step through the third upper sub-electrode patterned mask 72, the width of the third upper sub-electrode 233 is less than the width of the lower electrode 21, and the width of the part of the resistive layer 22 disposed on the upper surface of the lower electrode 21 is equal to the width of the third upper sub-electrode 233, so the finally formed resistive layer 22 covers part of the upper surface of the lower electrode 21. In this embodiment, the third upper sub-electrode and the resistive layer may be formed together through a one-step process, thereby reducing the process steps.

Referring to FIG. 8E, one layer of dielectric material is continuously deposited, so that the first dielectric layer 61 covers the third upper sub-electrode 233.

Referring to FIG. 8F, a plurality of upper metal layers 31 arranged in the first direction and extending in the second direction are formed; the upper metal layers 31 are disposed on the upper electrode 23, and each of the metal layers 31 is electrically connected to each upper sub-electrode.

In the embodiments of the present disclosure, the first upper sub-electrode and the second upper sub-electrode are formed on the two sides of the lower electrode, and the third upper sub-electrode is formed above the lower electrode, so that the device forms a 1T3R structure. The area of the resistive device in the related art is calculated according to the size of the plane, but in the present disclosure, the resistive device becomes a three-dimensional structure, the sizes of the first upper sub-electrode and the second upper sub-electrode on the two sides become the area of the side wall of the lower electrode, so the size of the resistive region can be changed by adjusting and controlling the height of the lower electrode, thereby increasing the integration level.

It should be understood that the steps may be reordered, added or deleted by using the flows in various forms, which are shown above. For example, the steps recorded in the present disclosure may be performed concurrently in order, or in a different order, provided that the desired result of the technical solutions disclosed in the present disclosure can be achieved, which is not limited herein.

In addition, the terms “first” and “second” are merely used for description purposes and cannot be interpreted as indicating or implying relative importance or implicitly indicating the number of technical features indicated. Therefore, the features defined with “first” and “second” can explicitly or implicitly include one or more features. In the description of the present disclosure, “a plurality of” means two or more than two, unless otherwise specified.

The above are only specific embodiments of the present disclosure, and are not intended to limit the scope of protection of the present disclosure, and any changes or substitutions that can readily occur to those skilled in the art within the scope of technology disclosed in the present disclosure should fall within the scope of protection of the present disclosure. Therefore, the scope of protection of the present disclosure shall be subject to the scope of protection of the claims.

What is claimed is:

1. A semiconductor structure, comprising:
a substrate; and
a plurality of resistive devices, disposed on the substrate; wherein each of the plurality of resistive devices comprises a lower electrode, a resistive layer and an upper electrode; the resistive layer covers a side wall and at least part of an upper surface of the lower electrode to isolate the lower electrode from the upper electrode; the upper electrode comprises a first upper sub-electrode, a second upper sub-electrode and a third upper sub-electrode, the first upper sub-electrode and the second upper sub-electrode are respectively disposed on two sides of the lower electrode, and the third upper sub-electrode is disposed on the lower electrode.

2. The semiconductor structure according to claim 1, wherein
upper surfaces of the first upper sub-electrode and the second upper sub-electrode are lower than or flush with the upper surface of the lower electrode.

3. The semiconductor structure according to claim 1, wherein
the plurality of resistive devices are arranged in an array in a first direction and a second direction, the first direction and the second direction are parallel to a plane of the substrate, and the first direction intersects with the second direction;
the first upper sub-electrode and the second upper sub-electrode respectively disposed on the two sides of the lower electrode comprises: the first upper sub-electrode and the second upper sub-electrode are respectively disposed on the two sides of the lower electrode in the first direction; and
the semiconductor structure further comprises: a plurality of upper metal layers arranged in the first direction and extending in the second direction, the plurality of upper metal layers are disposed on the upper electrode, and each of the plurality of upper metal layers is electrically connected to each of the first, second, and third upper sub-electrodes.

4. The semiconductor structure according to claim 3, wherein
the resistive layer covering the side wall and at least part of the upper surface of the lower electrode comprises: the resistive layer covers part of the upper surface of the lower electrode; and
a size of a part of the resistive layer disposed on the upper surface of the lower electrode in the first direction is equal to a size of the third upper sub-electrode in the first direction.

5. The semiconductor structure according to claim 1, further comprising:
a lower metal layer disposed on the substrate; wherein the lower metal layer is electrically connected to the lower electrode.

6. A preparation method for a semiconductor structure, comprising:
providing a substrate; and
forming a plurality of resistive devices on the substrate; wherein each of the plurality of resistive devices comprises a lower electrode, a resistive layer and an upper electrode, the resistive layer covers a side wall and at least part of an upper surface of the lower electrode to isolate the lower electrode from the upper electrode, the upper electrode comprises a first upper sub-electrode, a second upper sub-electrode and a third upper sub-electrode, the first upper sub-electrode and the second upper sub-electrode are respectively disposed on two sides of the lower electrode, and the third upper sub-electrode is disposed on the lower electrode.

7. The preparation method for the semiconductor structure according to claim 6, wherein a step of forming the plurality of resistive devices on the substrate comprises:
forming the lower electrode on the substrate;
forming the resistive layer completely covering the side wall and the upper surface of the lower electrode;
respectively forming the first upper sub-electrode and the second upper sub-electrode on two sides of the resistive layer;
forming a first dielectric layer, wherein the first dielectric layer covers upper surfaces of the first upper sub-electrode, the second upper sub-electrode and the resistive layer, and fills a gap between adjacent the two first upper sub-electrode and second upper sub-electrode;
etching and removing part of the first dielectric layer disposed on the upper surface of the resistive layer to form a first groove; and
forming the third upper sub-electrode in the first groove.

8. The preparation method for the semiconductor structure according to claim 6, wherein a step of forming the plurality of resistive devices on the substrate comprises:
forming the lower electrode on the substrate;
forming the resistive layer completely covering the side wall and the upper surface of the lower electrode;
forming a first dielectric layer, wherein the first dielectric layer covers upper surfaces of the first upper sub-electrode, the second upper sub-electrode and the resistive layer, and fills a gap between adjacent the two first upper sub-electrode and second upper sub-electrode;
etching and removing the first dielectric layer disposed on the upper surfaces of the first upper sub-electrode, the second upper sub-electrode and the resistive layer, and the resistive layer disposed on the upper surface of the lower electrode;
forming a first resistive layer covering the first upper sub-electrode, the second upper sub-electrode and the lower electrode;
forming an initial third upper sub-electrode on the first resistive layer;
forming a third upper sub-electrode patterned mask on the initial third upper sub-electrode; and
using the third upper sub-electrode patterned mask to etch and remove the initial third upper sub-electrode and the first resistive layer, wherein the initial third upper sub-electrode and the first resistive layer are not covered with the third upper sub-electrode patterned mask, retaining the initial third upper sub-electrode disposed on the lower electrode to form the third upper sub-electrode, and retaining the first resistive layer disposed below the third upper sub-electrode, the first resistive layer forming one part of the resistive layer.

9. The preparation method for the semiconductor structure according to claim 6, wherein
upper surfaces of the first upper sub-electrode and the second upper sub-electrode are lower than or flush with the upper surface of the lower electrode.

10. The preparation method for the semiconductor structure according to claim 6, wherein
the plurality of resistive devices are arranged in an array in a first direction and a second direction, the first direction and the second direction are parallel to a plane of the substrate, and the first direction intersects with the second direction;
a step of disposing the first upper sub-electrode and the second upper sub-electrode on the two sides of the lower electrode respectively comprises: the first upper sub-electrode and the second upper sub-electrode are respectively disposed on the two sides of the lower electrode in the first direction; and
wherein the preparation method for the semiconductor structure further comprises: forming a plurality of upper metal layers arranged in the first direction and extending in the second direction; wherein the plurality of upper metal layers are disposed on the upper electrode, and each of the upper metal layers is electrically connected to each of the first, second, and third upper sub-electrodes.
